(19) United States
(12) Patent Application Publication
(10) Pub. No.: US 2007/0254450 A1
(43) Pub. Date: Nov. 1, 2007

(54) Process for forming a silicon-based single-crystal portion

(75) Inventors: Didier Dutartre, Meylan (FR); Florence Brossard, Grenoble (FR); Benoit Vandelle, Meylan (FR); Florence Deleglise, Lumbin (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 11/788,029

(22) Filed: Apr. 18, 2007

(30) Foreign Application Priority Data
Apr. 19, 2006 (FR) 0603454

(51) Int. Cl. H01L 21/76

(52) U.S. Cl. 438/406

(57) ABSTRACT

A silicon-based single-crystal portion is produced on a substrate selectively in a zone where a single-crystal material is initially exposed. The portion is produced outside other surface zones where the surface of the substrate is made of insulating material. The single-crystal portion is formed from a gas mixture including a silicon precursor of the non-chlorinated hydride type, hydrogen chloride and a carrier gas. The process makes it possible to reduce the temperature at which the substrate has to be heated in order to form the single-crystal portion by selective epitaxial growth.

### PRIORITY CLAIM

The present application is a translation of and claims priority from French Patent Application No. 06 03454 of the same title filed Apr. 19, 2006, the disclosure of which is hereby incorporated by reference.

### BACKGROUND OF THE INVENTION

1. Technical Field of the Invention

The present invention relates to a process for forming a silicon-based single-crystal portion on the surface of a substrate. In particular, this process may be carried out during the fabrication of an integrated electronic circuit.

2. Description of Related Art

Many integrated electronic circuit architectures require the production, on a substrate, of portions of a substantially single-crystal semiconductor material. Such portions may be used for example to form source and drain zones of MOS transistors that are raised, that is to say they are located above the surface of the substrate, or to produce heterojunction bipolar transistors.

It is known to produce substantially single-crystal portions starting from exposed parts of the substrate, which are themselves made of single-crystal material. The single-crystal parts of the substrate serve as seeds for forming the portions. Such a way of forming the portions is called epitaxial growth. Outside the single-crystal parts of the substrate, the surface of the substrate may consist of insulating material, such as silica (SiO₂) or silicon nitride (Si₃N₄). The material of the portions formed is in general silicon, or a silicon-germanium alloy, which may also include carbon atoms. The deposition process most often used for epitaxial growth is CVD (chemical vapor deposition). The layer is then formed from gaseous precursor compounds that are brought into contact with the surface of the substrate and chemically react thereon. Such a process is generally carried out in a vacuum chamber.

Substantially single-crystal portions are formed, using the compound dichlorosilane (SiH₂Cl₂) as gaseous silicon precursor, in the substrate zones where the exposed surface is made of an initially single-crystal material. Simultaneously, amorphous, or possibly polycrystalline, portions are formed in the substrate zones where an insulating material is exposed, or even no portion is formed in the latter zones. In this case, the process for forming the single-crystal portion is called “selective epitaxial growth”. Most often a gas mixture is used that comprises, apart from the dichlorosilane compound, of hydrogen (H₂) molecules and germanium hydride (GeH₄) molecules. The deposition parameters comprise the partial pressures of the gaseous compounds, the temperature of the substrate and the amount of hydrogen chloride (HCl) that is added to the mixture. These parameters may be adjusted so as to obtain a defined degree of deposition selectivity between substrate zones where the surface is made of single-crystal material and substrate zones where the surface is made of insulating material.

However, such a process, which is based on the use of the compound dichlorosilane, has kinetic characteristics that vary very rapidly with the temperature of the substrate. More particularly, satisfactory deposition selectivity is achieved only for high substrate temperatures within a very narrow temperature range and within a narrow hydrogen chloride partial pressure range. As a result, the layers deposited have poor reproducibility characteristics, especially in regard to their selectivity with respect to the material of the substrate that is exposed in different zones. Furthermore, the selectivity obtained depends on the dimensions of the various substrate zones. Finally, the single-crystal portions are formed under selective conditions, from a dichlorosilane/hydrogen chloride mixture, with a low growth rate. The deposition process must therefore be continued for a long time in order to obtain layers that have thicknesses compatible with the architecture of the integrated electronic circuit. Consequently, the deposition process limits the fabrication output that can be achieved on an integrated electronic circuit production line.

It is also known to use disilane (Si₂H₆) and gaseous chlorine (Cl₂) to selectively deposit a silicon-based substantially single-crystal material. In particular, the disilane and the chlorine may be brought into contact with the substrate alternately, and the selectivity of the layers deposited results from a latency time, after which deposition takes place in the substrate zones where an amorphous or insulating material is exposed. However, such a process is implemented only under ultra high-vacuum conditions and the alternation between introducing disilane and introducing chlorine requires very lengthy treatment times. Furthermore, this process is sensitive to the temperature of the substrate, which is roughly equivalent to the temperature at which the dichlorosilane is used. Said process therefore does not significantly improve the production yield for integrated electronic circuits, nor does it reduce the requirement to control the temperature of the substrate.

There is a need in the art to provide a process for producing a silicon-based single-crystal portion, which process is selective with respect to the material of the substrate exposed in different zones and does not have the drawbacks indicated above.

### SUMMARY OF THE INVENTION

To address the foregoing and other needs, a process is provided for forming at least one substantially single-crystal silicon-based portion on a surface of a substrate selectively in a first zone of the substrate, in which zone a substantially single-crystal silicon-based material forming part of the substrate is initially exposed, and not in a second zone of the substrate, in which a material other than the substantially single-crystal material forming part of the substrate is exposed. The substrate is heated and brought into contact with a gas mixture comprising molecules of at least one non-chlorinated silicon hydride, molecules of hydrogen chloride and molecules of a carrier gas, at its surface in the first and second zones. The silicon hydride and the hydrogen chloride have respective partial pressures between 0.01 and 0.3 torr and the molecules of the carrier gas have a partial pressure between 10 and 100 torr.

Thus, a process is provided for the epitaxial deposition of a silicon-based material, this process being selective with respect to the material initially present on the surface of the substrate. The portion that is formed in that zone of the substrate where the surface is made of single-crystal material is directly obtained in single-crystal form, by epitaxial growth. A subsequent crystallization heat treatment is therefore unnecessary. Furthermore, no silicon is deposited on the substrate in the second zone, especially when an insulating and/or amorphous material is exposed in this second zone.

Such a process is based on the use of a compound of the non-chlorinated hydride type as silicon precursor. By choosing such a precursor compound, the temperature to which the substrate must be heated in order to form the single-crystal portion may be lower. This temperature may especially be 50° C. below the temperatures used in selective epitaxial deposition processes known in accordance with the prior art discussed herein. As a result, the thermal budget undergone by already produced parts of an integrated electronic circuit comprising the portion of single-crystal layer is lower. In particular, there is less atomic diffusion between parts of the circuit consisting of different materials. Furthermore, thanks to the low thermal budget, the circuit may also contain portions of fragile, thermally metastable or unstable, materials without these portions being impaired during formation of a single-crystal portion according to the invention.

Furthermore, the use of a compound of the non-chlorinated hydride type as silicon precursor makes it possible for the portion to be formed more rapidly. In other words, the reaction system used has more rapid kinetics.

Portions formed according to the methods described herein at different points on one and the same substrate have substantially identical thicknesses. Such thickness uniformity results from the stability of the process with respect to possible variations in deposition parameters within a substrate treatment chamber.

Finally, successive layers, exhibiting good repeatability, are readily deposited by the process, given that the deposition parameters that are controlled can be easily measured accurately.

The substantially single-crystal material forming part of a substrate that is initially exposed in the zone where the single-crystal portion is formed, called the first zone, may itself be based on optionally doped silicon or made of a silicon/germanium alloy that may furthermore include a certain amount of carbon. Outside this first zone, the substrate may comprise parts of an electrically insulating material exposed at its surface and/or parts of an amorphous material. Preferably, a silica (SiO₂) or silicon nitride (Si₃N₄) material is exposed on the surface of the substrate in the second substrate zone. In particular, deposition selectivity is obtained even when the area of exposure of the single-crystal material forming part of the substrate has small dimensions, especially when it represents an area 8 to 10 times smaller than the area of exposure of the electrically insulating materials.

The non-chlorinated silicon hydride compound used in the process may in particular be monosilane (SiH₄), disilane (Si₂H₆) or trisilane (Si₃H₈). Such compounds are commercially available and are inexpensive.

The molecules of the carrier gas may be hydrogen (H₂) or nitrogen (N₂) molecules.

Optionally, the gas mixture may furthermore include at least one germanium or carbon compound. The substantially single-crystal portion formed in the first substrate zone therefore incorporates germanium or carbon atoms. In particular, germanium hydride (GeH₄) may be chosen as germanium compound and methylsilane (SiH₃CH₃) as carbon compound. For some applications of the single-crystal portion formed, the amount(s) of the germanium and/or carbon compound(s) that is (are) added to the gas mixture may be adjusted so as to obtain predetermined stresses in the portion. For example, prestressed MOS transistor channels may be produced in this way.

Likewise, the gas mixture may also include a compound of an electrically doping element for silicon, in the case of the substantially single-crystal portion formed in the first substrate zone. As an example, hydrogen diboride (B₂H₆) may in particular be added to the gas mixture. The amount of compound/doping element in the gas mixture may also be adjusted in the gas mixture so as to obtain a predetermined concentration of the doping element in the substantially single-crystal portion.

In an embodiment, a process comprises: heating a single crystal silicon substrate to a temperature of between 600° C. and 750° C. in a treatment vacuum, a top surface of the substrate having first silicon zones and second isolation zones; and flowing a gas mixture over the single crystal silicon substrate comprising molecules of at least one non-chlorinated silicon hydride, molecules of hydrogen chloride and molecules of a carrier gas, the molecules of the silicon hydride and the hydrogen chloride each having a respective partial pressure between 0.01 and 0.3 torr and the molecules of the carrier gas having a partial pressure between 10 and 100 torr, so as to epitaxially grow, only on the first silicon zones, substantially single crystal structures.

In an embodiment, a process comprises: heating a single crystal silicon substrate to a temperature of between 450° C. and 650° C. in a treatment vacuum, a top surface of the substrate having first silicon zones and second isolation zones; and flowing a gas mixture over the single crystal silicon substrate comprising molecules of at least one non-chlorinated silicon hydride, molecules of germanium hydride, molecules of hydrogen chloride and molecules of a carrier gas, the molecules of the silicon hydride and the hydrogen chloride each having a respective partial pressure between 0.01 and 0.3 torr, the molecules of germanium hydride having a partial pressure between 0.6 and 6 mtorr and the molecules of the carrier gas having a partial pressure between 10 and 100 torr, so as to epitaxially grow, only on the first silicon zones, silicon-germanium alloy structures.

### BRIEF DESCRIPTION OF THE DRAWINGS

Other specific features and advantages will become apparent in the following description of a non-limiting exemplary embodiment, which makes reference to the appended drawings, in which:

FIG. 1 shows schematically a device for treating a substrate suitable for implementing a process for forming at least one substantially single-crystal silicon-based portion; and

FIG. 2 illustrates schematically an integrated electronic circuit substrate treated in accordance with the process.

### DETAILED DESCRIPTION OF THE DRAWINGS

For the sake of clarity, the dimensions of the elements shown in these figures are not in proportion with actual dimensions or dimensional ratios. N is a direction perpendicular to a surface of an integrated electronic circuit substrate. N is directed upwards in the figures. The words “on” and “beneath” used in the rest of the description refer to this orientation. Furthermore, identical references in two figures denote identical elements.

An integrated electronic circuit substrate, reference 100 in the figures, is made of single-crystal silicon. This may be a commercially available substrate, for example one for producing circuits in MOS (metal-oxide semiconductor) technology. It has a planar upper face denoted by S. Parts 102 of insulating material have been formed in the substrate 100, starting from the surface S, so as to define reduced areas 101 of the surface S in which the single-crystal silicon material of the substrate 100 is exposed. The parts 102 may for example be made of silica (SiO₂), especially when they are of the STI (shallow trench isolator) type. The zone 101 of the surface S may be intended for the production of active electronic components and are usually called “active zones”.

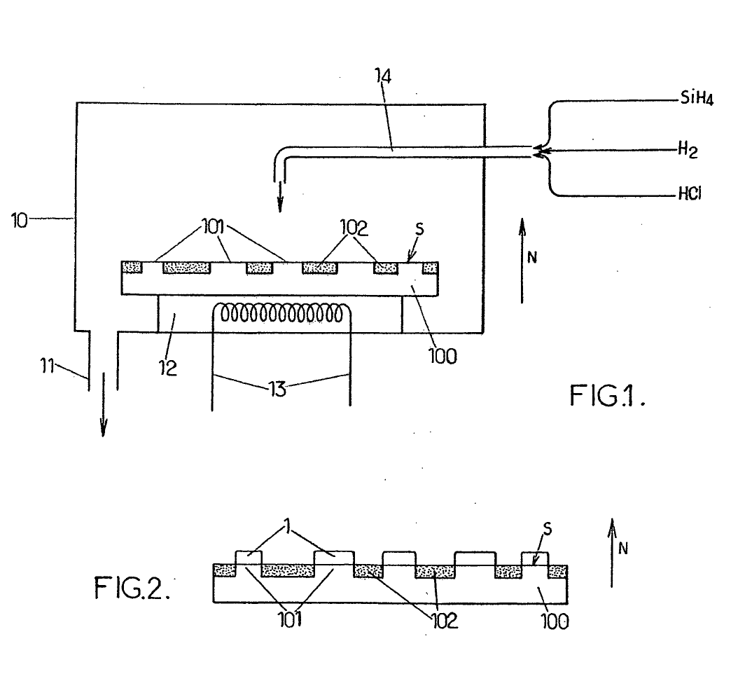

According to FIG. 1, the substrate 100 is placed in a vacuum chamber 10 connected to a pumping unit (not shown) via an evacuation orifice 11. The pumping unit creates a vacuum inside the chamber 10, suitable for the treatments applied to the substrate 100. The substrate 100 is fixed to a support 12, which is provided with a heating system 13. A line 14 is used to introduce gases into the chamber 10 so that these gases come into contact with the surface S of the substrate 100.

The formation of substantially pure silicon portions on the surface S of the substrate 100 will firstly be described. To do this, the substrate 100 is initially heated at a temperature between 600° C. and 750° C. A gas mixture comprising monosilane (SiH₄), hydrogen chloride (HCl) and a carrier gas, which may be hydrogen (H₂), is introduced into the chamber 10 via the line 14. Alternatively, nitrogen (N₂) may be used as carrier gas. The term “carrier gas” is understood to mean a dilution gas that does not participate directly in a chemical reaction inside the chamber 10 but does contribute to establishing a particular gas pressure during the substrate treatment. The respective monosilane, hydrogen chloride and carrier gas flow rates may be determined so that these gases have respective partial pressures between 0.01 and 0.3 torr in the case of silane and hydrogen chloride, and between 10 and 100 torr in the case of the carrier gas. Such a deposition process is of the RTCVD (rapid thermal chemical vapor deposition) type.

Under these temperature and partial pressure conditions, portions 1 (FIG. 2) are formed by epitaxial growth in the zones 101 of the surface S of the substrate 100. These portions 1 grow progressively along the direction N and each have a substantially single-crystal structure. The portions 1 are formed exclusively in the zones 101, with a growth rate between 1 and 50 nm/min (nanometers per minute), considering the change in thickness of the portions 1 in the direction N. The deposition may be continued until the portions 1 have a thickness for example of 0.5 μm (0.5 microns) in the direction N. The parts 102 remain exposed: no material is deposited on them.

According to one interpretation, the selective epitaxial deposition obtained results from reaction mechanisms based mainly on hydride chemistry in the zones 101 and based on mechanisms involving chloride-type entities on the parts 102.

Optionally, a precursor compound of an electrically doping element may be introduced into the chamber 10 via the line 14, simultaneously with the monosilane, the hydrogen chloride and the carrier gas. When the doping element is boron, the compound hydrogen diboride (B₂H₆) may be used. When the doping element is phosphorus or arsenic, the compound phosphorus hydride (PH₃) or the compound arsenic hydride (AsH₃) may be used, respectively. The amount of the doping element compound introduced into the gas mixture may then be adjusted empirically, so as to obtain a defined boron, phosphorus or arsenic concentration in the portions 1. High doping concentrations may thus be obtained. The portions 1 are therefore formed directly with a chosen value of electrical conductivity.

The formation of silicon-germanium alloy portions 1 using the process will now be described. The substrate 100 is heated at a temperature between 450° C. and 650° C. and germanium hydride (GeH₄) molecules are introduced into the chamber 10 via the pipe 14, together with the mixture of monosilane, hydrogen chloride and carrier gas. The partial pressure of the germanium hydride molecules may be between 0.6 and 6 mtorr (millitorr), and the partial pressures of the other gaseous species may be identical to those mentioned above in the case of the formation of substantially pure silicon portions 1. Under these conditions, portions 1 are still formed exclusively in zones 101 of the surface S of the substrate 100, but these portions are now made of a silicon-germanium alloy. The germanium content of these portions 1 is between 10 at % and 25 at %. It should also be pointed out that selective epitaxial deposition of alloy is obtained for a germanium hydride partial pressure that may vary within a particularly wide range.

Portions 1 of silicon incorporating carbon atoms may also be obtained, for example by introducing methylsilane (SiH₃CH₃) molecules simultaneously with the other reactive gases and with the carrier gas.

It should be understood that many adaptations may be introduced in the processes that have been described above. A person skilled in the art will understand that the numerical values mentioned are merely indicative and may be varied widely, while still retaining at least some of the advantages discussed herein. When the gas mixture comprises a germanium compound, this latter may have a partial pressure of between 0.2 and 6 mtorr. Furthermore, the substrate 100 used may be made of a silicon-germanium single-crystal alloy or it may include single-crystal parts made of a silicon-germanium-carbon ternary alloy, in the zones 101 lying between the insulating parts 102.

Finally, single-crystal portions formed according to the process may be used for many applications. For example, the production of prestressed MOS transistor channels, made of silicon-germanium alloy or of silicon incorporating carbon atoms, may be mentioned. Raised source and drain zones may also be obtained using the invention, especially on substrates of the SOI-MOS type (where SOI stands for silicon on insulator), and in particular when the single-crystal silicon surface layer of these substrates is very thin.

Although preferred embodiments of the method and apparatus have been illustrated in the accompanying Drawings and described in the foregoing Detailed Description, it will be understood that such is not limited to the embodiments disclosed, but is capable of numerous rearrangements, modifications and substitutions without departing from the spirit of the invention as set forth and defined by the following claims.

What is claimed is:

1. A process for forming at least one substantially single-crystal silicon-based portion on a surface of a substrate selectively in a first zone of the substrate in which zone a substantially single-crystal silicon-based material forming part of the substrate is initially exposed, and not in a second zone of the substrate in which a material other than said substantially single-crystal material forming part of the substrate is exposed, comprising:
heating the substrate;
bringing the substrate into contact with a gas mixture comprising molecules of at least one non-chlorinated silicon hydride, molecules of hydrogen chloride and molecules of a carrier gas, at said surface in said first and second zones, the molecules of the silicon hydride and the hydrogen chloride each having a respective partial pressure between 0.01 and 0.3 torr and the 1 molecules of the carrier gas having a partial pressure between 10 and 100 torr.

2. The process according to claim 1, in which a silica or silicon nitride material is exposed on the surface of the substrate in the second substrate zone.

3. The process according to claim 1, in which the non-chlorinated silicon hydride comprises one of monosilane, disilane or trisilane.

4. The process according to claim 1, in which the molecules of the carrier gas comprise hydrogen molecules and/or nitrogen molecules.

5. The process according to claim 1, in which heating the substrate comprises heating the substrate to a temperature of between 600° C. and 750° C.

6. The process according to claim 1, in which the gas mixture further includes at least one germanium compound or carbon compound and in which the substantially single-crystal portion formed in the first substrate zone incorporates one of germanium or carbon atoms.

7. The process according to claim 6, in which the quantity of germanium or carbon compound in the gas mixture is adjusted so as to obtain predetermined stresses in the substantially single-crystal portion formed in the first substrate zone.

8. The process according to claim 6, in which the gas mixture comprises a germanium compound and in which the substrate is heated at a temperature between 450° C. and 650° C.

9. The process according to claim 6, in which the gas mixture comprises a germanium compound having a partial pressure between 0.2 and 6 mtorr.

10. The process according to claim 1, in which the gas mixture further includes a compound of an electrically doping element for silicon and in which the amount of said compound of the doping element in the gas mixture is adjusted so that the substantially single-crystal portion formed in the first substrate zone incorporates the doping element with a predetermined concentration.

11. The process according to claim 10, in which the substantially single-crystal portion formed in the first substrate zone is part of a transistor.

12. A process, comprising:
heating a single crystal silicon substrate to a temperature of between 600° C. and 750° C. in a treatment vacuum, a top surface of the substrate having first silicon zones and second isolation zones; and
flowing a gas mixture over the single crystal silicon substrate comprising molecules of at least one non-chlorinated silicon hydride, molecules of hydrogen chloride and molecules of a carrier gas, the molecules of the silicon hydride and the hydrogen chloride each having a respective partial pressure between 0.01 and 0.3 torr and the molecules of the carrier gas having a partial pressure between 10 and 100 torr, so as to epitaxially grow, only on the first silicon zones, substantially single crystal structures.

13. The process of claim 12 wherein the carrier gas is hydrogen.

14. The process of claim 12 wherein the carrier gas is nitrogen.

15. The process of claim 12 wherein the carrier gas is a dilution gas.

16. The process of claim 12 wherein the gas mixture further comprises an element for electrically doping the epitaxially grown substantially single crystal structures.

17. The process of claim 16 wherein the element for doping is selected from the group consisting of boron, phosphorous and arsenic.

18. The process of claim 12 wherein the gas mixture further comprises methylsilane molecules so as to incorporate carbon atoms into the epitaxially grown substantially single crystal structures.

19. A process, comprising:
heating a single crystal silicon substrate to a temperature of between 450° C. and 650° C. in a treatment vacuum, a top surface of the substrate having first silicon zones and second isolation zones; and
flowing a gas mixture over the single crystal silicon substrate comprising molecules of at least one non-chlorinated silicon hydride, molecules of germanium hydride, molecules of hydrogen chloride and molecules of a carrier gas, the molecules of the silicon hydride and the hydrogen chloride each having a respective partial pressure between 0.01 and 0.3 torr, the molecules of germanium hydride having a partial pressure between 0.6 and 6 mtorr and the molecules of the carrier gas having a partial pressure between 10 and 100 torr, so as to epitaxially grow, only on the first silicon zones, silicon-germanium alloy structures.

20. The process of claim 19 wherein single crystal silicon substrate is made of a silicon germanium single crystal alloy.

21. The process of claim 19 wherein single crystal silicon substrate includes single crystal parts made of a silicon germanium carbon ternary alloy in the first silicon zones.

22. The process of claim 19 wherein the carrier gas is hydrogen.

23. The process of claim 19 wherein the carrier gas is nitrogen.

24. The process of claim 19 wherein the carrier gas is a dilution gas.

25. The process of claim 19 wherein the gas mixture further comprises an element for electrically doping the epitaxially grown silicon-germanium alloy structures.

26. The process of claim 25 wherein the element for doping is selected from the group consisting of boron, phosphorous and arsenic.

27. The process of claim 19 wherein the gas mixture further comprises methylsilane molecules so as to incorporate carbon atoms into the epitaxially grown silicon-germanium alloy structures.
